(19) United States
(12) Patent Application Publication
(10) Pub. No.: US 2014/0335700 A1
(43) Pub. Date: Nov. 13, 2014

(54) Carbon Layers for High Temperature Processes

(71) Applicant: Infineon Technologies AG, Neubiberg (DE)

(72) Inventors: Guenter Denifl, Annenheim (AT); Markus Kahn, Rangersdorf (AT); Helmut Schoenherr, Villach (AT); Daniel Maurer, Feld am See (AT); Thomas Grille, Villach (AT); Joachim Hirschler, Villach (AT); Ursula Hedenig, Villach (AT); Roland Moennich, Villach (AT); Matthias Kuenle, Villach (AT)

(21) Appl. No.: 13/892,003

(22) Filed: May 10, 2013

(51) Int. Cl. H01L 21/02; C23C 16/26

(52) U.S. Cl. CPC H01L 21/02115; C23C 16/26; H01L 21/02362
USPC 438/763; 118/723 R; 438/778

(57) ABSTRACT

Carbon layers with reduced hydrogen content may be deposited by plasma-enhanced chemical vapor deposition by selecting processing parameters accordingly. Such carbon layers may be subjected to high temperature processing without showing excessive shrinking.

### TECHNICAL FIELD

This application relates to the deposition of carbon layers followed by high temperature processes, corresponding apparatuses and devices having such carbon layers.

### BACKGROUND

Carbon layers, in particular so-called diamond-like carbon layers or films, have favorable properties which make it desirable to use such layers, for example, in manufacturing processes of semiconductor devices, for example, silicon-based devices.

In some applications, it is desirable to coat or encapsulate such carbon layers with further layers, for which the employment of furnace processes which require a comparatively high temperature may be desirable. However, for many conventionally deposited carbon films, for example, for hydrogenated carbon films, such a high temperature treatment may lead to high shrinkage of the carbon layer or even delamination of the carbon layer from the substrate, which is undesirable. Other conventionally deposited carbon layers may withstand such high temperature processes, but may have low growth rates, thus limiting their applicability, for example, in cases where a high growth rate is required.

### BRIEF DESCRIPTION OF THE DRAWINGS

FIG. 1 is a schematic view of a processing apparatus according to an embodiment;

FIG. 2 is a schematic view of a deposition apparatus according to an embodiment;

FIG. 3 is a flowchart illustrating a method according to an embodiment;

FIG. 4 is a diagram illustrating various processing possibilities for carbon layers according to embodiments; and

FIGS. 5A to 5D show cross-sectional views of carbon layers, with FIGS. 5A and 5B showing an example and FIGS. 5C and 5D showing a comparative example.

In the following, various embodiments will be described in detail. While various specifics and details regarding such embodiments are given, this is not implying that the application of the techniques and embodiments disclosed herein is limited to such specific details. The embodiments are to be seen as examples only, and other embodiments may be implemented in different manners than the ones shown. For example, other embodiments may comprise less features or alternative features.

Also, it has to be noted that features from different embodiments may be combined with each other unless specifically noted otherwise.

### DETAILED DESCRIPTION OF ILLUSTRATIVE EMBODIMENTS

Various embodiments relate to the deposition of carbon layers on substrates. The substrates may be pre-processed substrates, for example, semiconductor substrates where semiconductor devices have been formed or partially formed, and/or the carbon layer deposition may be part of an overall processing of the substrate to manufacture semiconductor devices. In some embodiments, a plasma-enhanced chemical vapor deposition (PECVD) process is used to deposit a carbon layer. In one or more embodiments, processing conditions are such that the carbon layer has a reduced hydrogen content via adding of dilution gas and/or inducing increased deposition power. In some embodiments, improved temperature stability of such films may be observed by using diluted processes. In various embodiments, carbon layers with increased temperature stability are manufactured which exhibit a shrink of less than 10% after annealing at 700° C. or less for 1 hour, or less than 5% after annealing at 800° C. or less for 2 hours. In some embodiments, for example, a precursor gas for the carbon deposition is diluted with a dilution gas, and other processing conditions like deposition temperature, plasma generator power or deposition pressure are adjusted to obtain a carbon layer which exhibits comparatively low shrinking, for example, a shrinking smaller than 10%, for example, about 5% or less, when treated in a high temperature treatment, for example, at temperatures at or above 500°, or even at 700° or more. Such low shrinking reduces problems with delamination of the carbon layer in various embodiments.

In some embodiments, such high temperature processing may comprise a heat treatment of the carbon layer and/or a deposition of a further layer like a nitride layer, an oxynitride layer, an oxide layer, in particular a deposited oxide layer, an amorphous silicon layer or a polysilicon layer on the carbon layer. Some embodiments relate to the deposition of carbon layers by PECVD having an increased density.

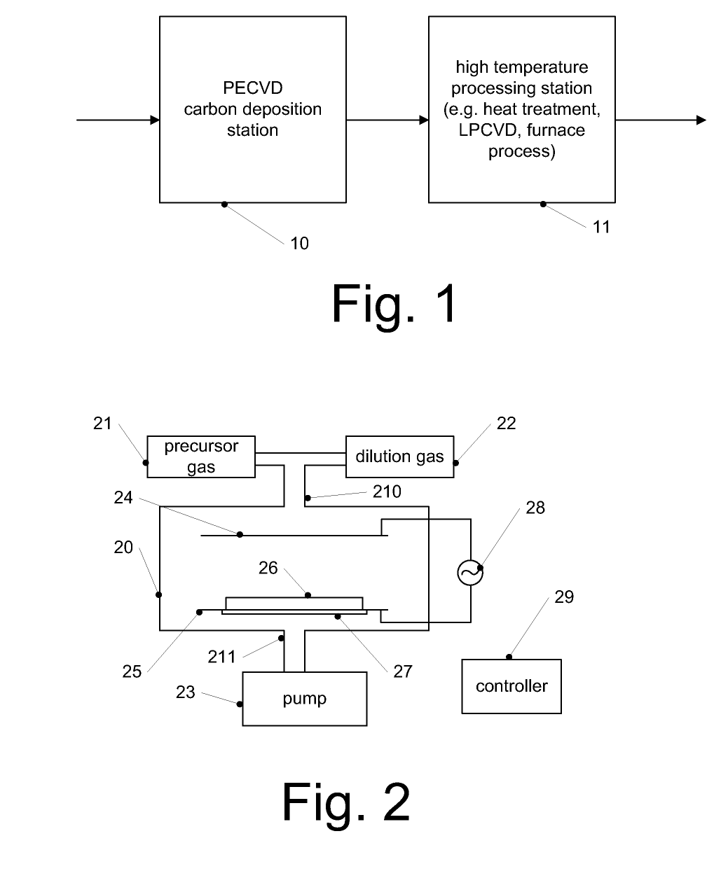

Turning now to the figures, in FIG. 1 a processing apparatus according to an embodiment is shown. The processing apparatus of FIG. 1 is shown as comprising a plasma-enhanced chemical vapor deposition (PECVD) carbon deposition device 10 and a high-temperature processing device 11, for example, a batch furnace. The processing apparatus of FIG. 1 may be part of a larger processing apparatus comprising further stations upstream of PECVD carbon deposition station 10 and/or downstream of high-temperature processing station 11. In other words, substrates may already be processed prior to entering PECVD carbon deposition device 10, and/or may be further processed after leaving high-temperature processing device 11. Also, in some embodiments one or more further devices may be provided between stations 10 and 11. The term “apparatus” does not imply any spatial relationship between the various devices comprised in the apparatus. In particular, different devices may also be located remote from each other, for example, in different rooms or in different parts of a room, with mechanisms being provided to transfer substrates from one device to the next. Also, a single device may be partitioned into several devices in some embodiments. These several devices may be located close together or remote from each other.

In PECVD carbon deposition device 10, a carbon layer is deposited by means of a plasma-enhanced chemical vapor deposition. An example for such a plasma-enhanced chemical vapor deposition will be explained later in detail with reference to FIG. 2.

In some embodiments, fast growing and/or durable carbon based layers with high thermal stability may be deposited by PECVD. Such embodiments may use one or more of the following features or combinations of such features. However, other embodiments may comprise other features and/or alternative features.
1. a diluting gas (e.g., nitrogen (N₂), helium (He), argon (Ar), etc.) may be added to a hydrocarbon gas used as a precursor gas in a PECVD process;
2. the carbon layer deposition may be performed at elevated deposition temperatures (≦900° C.);
3. the carbon layer deposition may be performed with a strong ion-bombardment at a high plasma generator power in a PECVD process;
4. the carbon layer deposition may be performed at a low deposition pressure; and
5. after the carbon layer deposition, a post-annealing, e.g., in a batch furnace, may be performed.

In some embodiments, the carbon layer deposited exhibits low shrinkage under high temperatures. In some embodiments, this may be achieved by providing a carbon layer with a reduced hydrogen content. In some embodiments, deposited carbon layers with high density may also be more stable against humidity after the deposition compared to conventional PECVD deposited carbon layers. This stability may be observed by the fact that a change of the intrinsic layer stress due to absorption of water molecules is small, for example, smaller than a measurement accuracy of typical measurement instruments, i.e., essentially the stress stays constant.

After deposition of the carbon layer in carbon deposition device 10, the substrate, for example, a semiconductor substrate like a silicon substrate, which as mentioned may be preprocessed, is transferred to high-temperature processing device 11. In high-temperature processing device 11, for example, a heat treatment of the substrate with the carbon layer, for example, at temperatures between 500° C. and 1,000° C., and/or a low-pressure chemical vapor deposition (LPCVD) process, for example, for coating or encapsulating the carbon layer with a further layer like a nitride layer, an oxynitride layer or a an oxide layer deposited by the LPCVD furnace process, may be performed.

In FIG. 2, a schematic view of a PECVD apparatus is schematically shown. The PECVD apparatus described in the following with reference to FIG. 2 may, for example, be used in carbon deposition device 10 of FIG. 1, but may also be used in other embodiments to deposit carbon layers.

The PECVD apparatus comprises a processing reactor chamber 20 which is shown in cross-section in FIG. 2. Gas may be supplied to processing reactor chamber 20 via a gas inlet 210. A precursor gas reservoir 21 and a dilution gas reservoir 22 are coupled to gas inlet 210 to supply a precursor gas, i.e., a gas containing the carbon to be deposited on a substrate 26, and a dilution gas, respectively. Via a controller 29 an amount of precursor gas and an amount of dilution gas supplied to processing reactor chamber 20 may be adjusted, wherein both amounts may be adjusted individually in some embodiments.

As a precursor gas, for example, hydrocarbon compounds CₓH_{y} may be used, for example, acetylene (C₂H₂), propylene (C₃H₆), propyne (C₃H₄), propane (C₃H₈) or others.

As dilution gas, for example, argon (Ar), helium (He), other noble gases, nitrogen (N₂) or mixtures thereof may be used.

Processing reactor chamber 20 further comprises a gas outlet 211 coupled with a pump 23 to remove gas from processing reactor chamber 20. To adjust a pressure in processing reactor chamber 20, for example, a so-called throttle valve (not shown) provided between pump 23 and processing reactor chamber 20 may be adjusted. Pump 23 and/or valves like the above-mentioned throttle valve associated with pump 23 and gas outlet 211 may be controlled by controller 29 to obtain a desired pressure within processing reactor chamber 20.

It should be noted while in FIG. 2 a single gas inlet 210 and a single gas outlet 211 are shown, also more than one gas inlet and/or more than one gas outlet may be provided. For example, precursor gas source 21 and dilution gas source 22 may be coupled with separate gas inlets in some embodiments.

Furthermore, processing reactor chamber 20 comprises two plate-like electrodes 24, 25 which are parallel to each other and which may be supplied via a radio frequency source (RF source) 28 controlled by controller 29. Substrate 26 is placed on electrode 25 such that substrate 26 may be powered accordingly. Furthermore, a heater 27 is provided, for example, a resistive heating element, to heat substrate 26 to a desired temperature. Heater 27 may also be controlled by controller 29.

By applying an appropriate power via RF source 28, a plasma is generated, which in turn leads to a deposition of a desired layer on substrate 26. The general setup shown in FIG. 2 corresponds to a conventional PECVD device and will therefore not be further described. Numerous variations are possible. For example, electrode 24 may have holes such that gas from gas inlet 210 may flow directly through electrode 24.

By choosing processing conditions during deposition of a carbon layer accordingly, it has turned out that layers may result which are suitable for undergoing subsequent high-temperature processing steps, for example, at temperatures at or above 500° C., with little shrinkage, for example less than 10% or less than 5%, which makes them less prone to problems like delamination, micro- and/or nanovoid formation and/or humidity adsorption than previous conventional carbon layers. This is of particular importance for carbon layers which are intended to remain in the device to be fabricated (in contrast to layers like sacrificial layers which are removed again later during processing and fabrication of the device). In particular, in some embodiments fast growing and durable carbon films with high thermal stability may be deposited in a PECVD apparatus like the one of FIG. 2:
with a dilution gas, for example, He, Ar or N₂, added to a hydrocarbon gas used as a precursor gas. For example, flow rates of the precursor gas may be in a range between about 100 sccm and 10,000 sccm, for example, about 750 sccm, although other values may also apply. Dilution gas, for example, nitrogen, may be supplied at a flow rate between about 100 sccm and about 30,000 sccm, for example, between about 6,000 sccm and about 10,000 sccm, for example, of the order of 7,500 sccm. For example, a ratio of the flow rate of the dilution gas to the flow rate of the precursor gas may be in the range between 100:1 and 1:1, for example, between 15:1 and 1:1.
at elevated deposition temperatures, for example, between about 200° C. and 900° C., for example, between 200° C. and 700° C.
at a high plasma generator power between for example about 100 W and about 10,000 W, for example, 1,000 W, with a frequency for example between 5 MHz and 50 MHz, and/or
at a low deposition pressure, for example, between 100 Pa and 1,500 Pa.

In some embodiments, only some or only one of the above features may be used, for example, only the use of a dilution gas. Adding further features from the list above in some embodiments may improve the results.

The above numerical values serve merely as examples, so that in other embodiments other values may be used as well. The numerical values may, e.g., strongly depend on a deposition device (e.g., PECVD device) used and a diameter of a substrate used. The values used may also depend on circumstances like the PECVD application.

In some embodiments, resulting carbon layers may have a reduced hydrogen content. A shrinkage and/or delamination or the carbon layer, e.g., during a subsequent high temperature process depend on the hydrogen content of the carbon layer, a lower hydrogen content in many cases corresponding to a reduced shrinkage and/or a reduced risk of delamination. Practically, absolute atomic amounts of hydrogen content are difficult to determine due to different bonding states within the layer and analytical errors. Thus, an appropriate method for hydrogen content and layer density estimation in some embodiments is to measure the layer shrinkage after a heat-treatment which is a function of hydrogen content and film density. In some embodiments, carbon layers exhibit a shrinkage of less than 10% after heat-treatment at a temperature of 700° C. or less for 1 hour or less or a shrinkage of less than 5% after heat-treatment at a temperature of 800° C. or less for 2 hours or less. It is to be noted that in this way, the shrinkage at certain heat treatments may be used as an indirect measure for film properties like hydrogen content and/or layer density. Therefore, defining a carbon layer, e.g., as showing a shrinkage of less than 10% after heat-treatment at a temperature of 700° C. or less for 1 hour or less does not imply that a heat-treatment at 700° or less is actually performed, but defines merely that the shrinkage would be 10% or less if such a heat-treatment were performed.

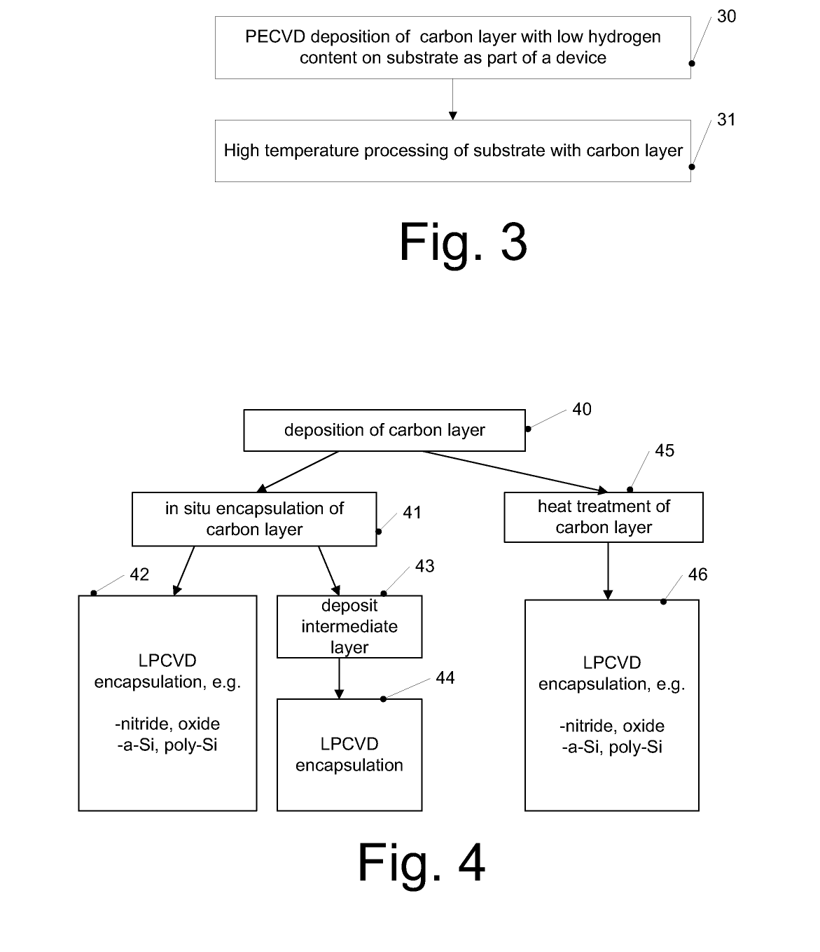

In FIG. 3, a flowchart representing a method according to an embodiment is shown. The method of FIG. 3 may, for example, be implemented using the apparatus of FIG. 1 or the apparatus of FIG. 2, but may also be implemented using other devices.

At 30, a carbon layer with reduced hydrogen content as explained above, i.e., leading to reduced shrinkage, is deposited on a substrate, the carbon layer forming a part of a device to be formed on the substrate, by means of plasma-enhanced chemical vapor deposition. “A part of the device” means that the carbon layer is not completely removed during subsequent processing (but it may be structured or the like). For example, processing parameters as described above with reference to FIG. 2 may be used for depositing the carbon layer.

At 31, subsequently a high temperature processing of the substrate with the carbon layer deposited thereon is performed. The high temperature processing may, for example, comprise a high temperature treatment or an encapsulation of the carbon layer by depositing a further layer on the carbon layer at high temperatures. High temperatures in this case refer to temperatures, for example, between 400° C. and 900° C., for example, between 500° C. and 800° C. In embodiments, a thermal budget of this high temperature processing is higher than the deposition temperature of the carbon layer. Various possibilities for such high temperature processing will be explained further below with reference to FIG. 4. By depositing the carbon layer with corresponding suitable process parameters as explained above, a shrinkage of the carbon layer during the high temperature processing may be reduced compared to conventional solutions, for example, to at or below 10% or at or below 5%, which reduces a risk for delamination of the carbon layer or other problems due to shrinkage. In this way, in some embodiments, carbon layers may be integrated in the device manufacturing process.

Next, with reference to FIG. 4 various possibilities for high temperature processing of a substrate after a deposition of a carbon layer at 40 will be discussed. The deposition of the carbon layer at 40 may be performed as described previously with reference to FIGS. 1-3.

In some embodiments, as indicated by 41 an encapsulation of the carbon layer may be performed, for example, immediately after the deposition of the carbon layer. In this respect, in the context of this application “encapsulation of the carbon layer” is used essentially interchangeably with “depositing a further layer on the carbon layer,” the further layer then serving for encapsulating or covering the carbon layer.

In some embodiments, the encapsulation is performed using a low pressure chemical vapor deposition (LPCVD). For example, a nitride like a silicon nitride, an oxide like a silicon oxide or an oxynitride may be deposited. Temperatures during this deposition may be between 500° C. and 900° C., for example, between 600° C. and 800° C. The deposited nitride or oxynitride layer may have a thickness between 10 nm and 400 nm, for example, between 10 nm and 200 nm. The deposited oxide layer may have a thickness between 10 nm and 2 μm, for example, between 10 nm and 500 nm. In other embodiments, an amorphous silicon layer (a-Si) or a polycrystalline silicon layer (poly-Si) may be deposited. Typical temperatures for the silicon layer deposition may be in the range of 500° C. to 700° C., for example, 520° C. to 630° C., and layer thicknesses may be between a few nm up to an order of some 100 nm.

In other embodiments, prior to a LPCVD encapsulation at 43 an intermediate layer, for example, a layer to improve adhesion of the subsequent LPCVD deposited layer, may be deposited. For example, at 43 an amorphous silicon layer with a thickness of some nanometers may be deposited. Following this, at 44 an encapsulation layer may be deposited using, for example, tetraethylorthosilicate (TEOS) as a precursor gas to deposit a silicon oxide. However, other layers, for example, as mentioned with respect to 42, may also be deposited. The encapsulation at 44 may, for example, be performed at temperatures between 500° C. and 800° C., for example, between 600° C. and 700° C.

In other embodiments, instead of performing an encapsulation, for example, immediately after the deposition of the carbon layer, at 45 a heat treatment of the carbon layer is performed. Such a heat treatment may be performed in a furnace at temperatures between 500° C. and 1,000° C., for example, at about 800° C. During the heat treatment, an inert gas, for example, nitrogen (N₂), may be supplied.

After this heat treatment, later on at 46 an LPCVD encapsulation may be performed, for example, with a nitride, a deposited oxide, an oxynitride, amorphous silicon or polycrystalline silicon, as, for example, already explained with respect to 42.

It is to be noted that the various possibilities given with reference to FIG. 4 are not to be seen as exhaustive and other kinds of high temperature processing may also be performed after the deposition of the carbon layer. Furthermore, the numerical values given with respect to FIG. 4 serve only as examples, and other values, for example, other temperatures, other materials or other layer thicknesses, are also possible.

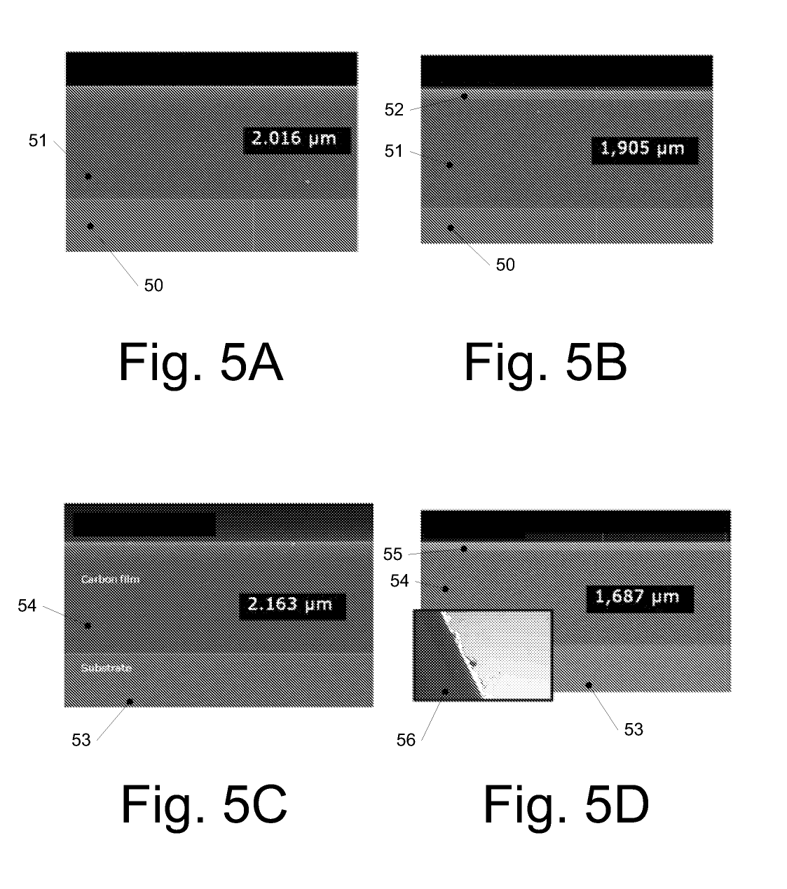

Next, with reference to FIGS. 5A and 5B cross-sectional views of layers and devices manufactured according to embodiments are shown. FIGS. 5C and 5D show comparative examples.

FIG. 5A shows a cross-sectional electron microscopy view of a PECVD carbon layer 51 deposited on a silicon substrate 50 under procession conditions as explained with reference to FIG. 2 leading to a low hydrogen content. Carbon layer deposited under such conditions may have a high density. The thickness of carbon layer 51 has been measured as 2.016 μm, as in the case of FIG. 5A.

FIG. 5B shows the structure of FIG. 5A after a nitride layer 52 has been deposited in a high temperature LPCVD furnace process. After this high temperature process, the thickness of carbon layer 51 has been measured as 1.905 μm, which corresponds to a shrinkage of about 5%.

In the comparative examples of FIGS. 5B and 5C, a carbon layer 54 has been deposited on a silicon substrate 53 using conventional PECVD parameters, which leads to a comparatively high hydrogen content of about 30% to 50%. The thickness of the carbon layer of the deposition as shown in FIG. 5C has been measured as 2.163 μm.

Similar to FIG. 5B, an LPCVD nitride layer 55 has been deposited on top of carbon layer 54. In this case, this led to a shrinking of carbon layer 54 to 1.687 μm, which corresponds to a shrinkage of about 25%. As shown in an insert 56, such a high shrinkage leads to a partial delamination of the layer.

The above cross-sectional electron microscopy images serve only for further illustrating embodiments, and depending on the application other layer thicknesses may be used, and/or carbon layers may be deposited on already processed substrates or other substrates than silicon substrates.

What is claimed is:

1. A method comprising:
depositing a carbon layer with a hydrogen content on a substrate using plasma enhanced chemical vapor deposition (PECVD), the hydrogen content being such that a shrinkage of the carbon layer is below 10% at any heat-treatment of the carbon layer at a temperature below 700° C. for 1 hour or less; and
performing a processing of the carbon layer at a temperature of at least 400° C.

2. The method of claim 1, wherein said shrinkage of the carbon layer is below 5% at any heat-treatment of the carbon layer at 800° C. or below for 2 hours or less.

3. The method of claim 1, wherein said carbon layer has a time stability against water and humidity absorption such that a stress of the carbon layer essentially stays constant over time.

4. The method of claim 1, wherein depositing the carbon layer comprises supplying a precursor gas and a dilution gas to a processing reactor chamber.

5. The method of claim 3, wherein the dilution gas comprises at least one of helium, argon or nitrogen.

6. The method of claim 3, wherein said precursor gas comprises at least one of a hydrocarbon gas.

7. The method of claim 1, wherein said processing comprises performing a heat treatment at least 500° C.

8. The method claim 1, wherein said processing comprises a deposition of an encapsulation layer on the carbon layer.

9. The method of claim 8, wherein said deposition of said encapsulation layer is performed at a temperature of at least 500° C.

10. The method of claim 8, wherein said encapsulation layer comprises at least one of a nitride, an oxide, an oxynitride, amorphous silicon or polycrystalline silicon.

11. The method of claim 1, wherein said processing comprises a low pressure chemical vapor deposition (LPCVD) process.

12. A method comprising:
depositing a carbon layer using a plasma-enhanced chemical vapor deposition (PECVD) process; and
depositing a further layer on said carbon layer at a temperature of at least 500° C., wherein a shrinkage of said carbon layer during depositing the further layer is less than 10%.

13. The method of claim 12, wherein said shrinkage is less than 5%.

14. An apparatus comprising a plasma-enhanced chemical vapor deposition (PECVD) device configured to deposit a carbon layer with a hydrogen content on a substrate, the hydrogen content being such that a shrinkage of the carbon layer is below 10% at any heat-treatment of the carbon layer at a temperature below 700° C. for 1 hour or less.

15. The apparatus of claim 14, further comprising a high temperature processing device configured to process said carbon layer at a temperature of at least 400° C.

16. The apparatus of claim 15, wherein said high temperature processing device comprises a batch furnace.

17. The apparatus of claim 14, comprising a low pressure chemical deposition (LPCVD) processing device configured to encapsulate said carbon layer at a temperature of at least 500° C.

18. The apparatus of claim 17, wherein said LPCVD processing device is configured to deposit at least one of a nitride layer, an oxynitride layer, an oxide layer, an amorphous silicon layer or a polycrystalline silicon layer.

19. The apparatus of claim 14, wherein said PECVD device comprises a precursor gas source and a dilution gas source.

20. The apparatus of claim 14, wherein said PECVD device is configured to operate at a pressure below 1,500 Pa and at a temperature above 200° C. when depositing said carbon layer.

21. A device comprising:
a substrate; and
a plasma-enhanced chemical vapor deposition-deposited carbon layer with a hydrogen content, the hydrogen content being such that a shrinkage of the carbon layer is below 10% at any heat-treatment of the carbon layer at a temperature below 700° C. for 1 hour or less.

22. The device of claim 21, further comprising an encapsulation layer on said carbon layer.

23. The device of claim 22, wherein said encapsulation layer comprises at least one of a nitride, a deposited oxide, an oxynitride, amorphous silicon or polycrystalline silicon.

24. The device of claim 21, wherein the hydrogen content is such that a shrinkage of the carbon layer is below 5% at any heat-treatment of the carbon layer at a temperature below 800° C. for 1 hour or less.
